(19) United States
(12) Patent Application Publication
(10) Pub. No.: US 2005/0139858 A1
(43) Pub. Date: Jun. 30, 2005

(54) Lateral double-diffused MOS transistor device

(76) Inventor: Woong Je Sung, Bucheon-si (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/027,348

(22) Filed: Dec. 29, 2004

(30) Foreign Application Priority Data
Dec. 31, 2003 (KR) 10-2003-0101105

(51) Int. Cl. H01L 29/74

(52) U.S. Cl. 257/122

(57) ABSTRACT

A lateral double-diffused metal oxide semiconductor is disclosed. An example LDMOS transistor includes a semiconductor substrate of a first conductivity type, a first buried layer of a second conductivity type on the semiconductor substrate, an epitaxial layer of the second conductivity type on the first buried layer, a body region of the first conductivity type in the upper part of the epitaxial layer, and a second buried layer of the first conductivity type between the body region and the first buried layer. The example transistor also includes a source region of the second conductivity type in the upper part of the body region, a drain region of the second conductivity type in the upper part of the epitaxial layer, and a third buried layer of the second conductivity type between the drain region and the first buried layer.

### TECHNICAL FIELD

The present disclosure relates to a lateral double-diffused metal oxide semiconductor (hereinafter referred to as “LDMOS”) and, more particularly, to an LDMOS transistor that has an improved current driving force.

### BACKGROUND

Because MOS field effect transistors (hereinafter referred to as “MOSFET”) have higher input impedance than bipolar transistors, their power gains are high and their gate driving circuits are very simple. Generally, when devices are turned off, minority carrier storage or minority carrier recombination causes time delay. However, because the MOSFET is a unipolar device, it has the benefit of having substantially no time delay. Thus, its applications, such as switching mode power supplies, lamp ballast and motor driving circuits, are expanding. MOSFETs usually utilize a DMOSFET (double diffused MOSFET) structure embodied by a planar diffusion technology. A typical LDMOS transistor is disclosed in U.S. Pat. No. 4,300,150 to Sel Cloak. Additionally, an LDMOS transistor integrated with a CMOS transistor and a bipolar transistor, is disclosed on pages 322-327 of the “ISPSD 1992” in a paper entitled “A 1200 BiCMOS Technology and Its Application,” by Vladimir Rumennik and on pages 343-348 of the “ISPSD 1994” in a paper entitled “Recent Advances in Power Integrated Circuits with High Level Integration,” by Stephen P, Robb.

It is important for DMOS transistors to be applied to power devices that can handle high voltage. One important feature of power devices is to have good characteristics for a current handling capacity per unit area or an ON-resistance per unit area. Because a voltage ratio is fixed, the ON-resistance per unit area can be reduced due to a decrease of a cell area of the MOS device.

In the field of power transistors, a cell pitch of a device is determined by the combined width of a polysilicon region and a contact region, which form a gate electrode and a source electrode, respectively. For DMOS power transistors, as a method for diminishing the width of a polysilicon region, reducing a P-type well junction depth is well-known. However, a predetermined breakdown voltage restricts the junction depth.

A known LDMOS device is well applied to a VLSI process due to its simple structure. Nevertheless, these LDMOS devices have been regarded as less attractive than VDMOS (vertical DMOS) devices. Recently, RESURF (reduced surface field) LDMOS devices have a good ON-resistance characteristic. However, their structure is very complex, applied only for the devices having earthed sources, and difficult to use in other applications.

Particularly, in the past, DMOS transistors were used as discontinuous power transistors or elements of monolithic integrated circuits. Because the DMOS transistors are fabricated according to self-aligned manufacturing procedure, they basically comprise a semiconductor substrate.

To form a self-aligned channel region with a gate electrode, a channel body region is generally formed by implanting either p-type dopants or n-type dopants through apertures within a mask, which is made of materials for the gate electrode. Additionally, a source region is formed by implanting conductive dopants opposite to those used for the channel body region. The source region is then self-aligned to both the gate electrode and the channel body region, thereby providing a compact DMOS transistor structure.

Referring to FIG. 1, an LDMOS transistor device 10 actually has two LDMOS transistors 10a and 10b. The transistor device 10a is formed on a SOI (silicon on insulator) substrate comprising a silicon substrate 11, a buffer oxide layer 12 and a semiconductor layer 14. Here, the semiconductor layer 14 is formed over the silicon substrate 11. A known FET (field effect transistor) comprises a source region 16a and a drain region 18a. The N-type doped source region 16a is formed within a P-type doped well region 20. The well region 20 is often called a P-type body. The P-type body 20 may extend to the upper surface of the buffer oxide layer 12 or be only within the semiconductor layer 14.

The drain region 18a contacts one end of a field insulation region 23a. The field insulation region 23a includes a field oxide layer such as a thermally grown silicon oxide layer. A gate electrode 26a is formed on the surface of the semiconductor layer. The gate electrode 26a extends from the upper part of the source region 16a to the upper part of the field insulation region 23a. The gate electrode 26a is made of polysilicon doped with impurities. The gate electrode 26a is isolated from the semiconductor layer 14 by a gate dielectric 28a. The gate dielectric 28a may comprise oxide, nitride or any combination thereof (e.g., stacked NO or ONO layer)

Sidewall insulation regions (not shown) may be formed on the sidewalls of the gate electrode 26a. The sidewall insulation regions commonly comprise oxide such as silicon oxide or nitride such as silicon nitride. A body region 30 doped at a high concentration exists within the P-type body 20, making good contact with the P-type body 20. The body region 30 is doped at a higher concentration than the P-type body 20.

A source contact plug 34 and a drain contact plug 32a exist within the transistor device 10a. The contact plugs 34 and 32a are provided to electrically connect the source region 16a and the drain region 18a to other elements of the circuit. Referring to FIG. 1, the single contact plug 34 is used for source regions, 16a and 16b, of two transistors, 10a and 10b. The prior technology as described above was disclosed in U.S. Pat. No. 5,369,045 to Ng et al.

However, for the foregoing method, because N-type wells have a uniform concentration profile, electric field is concentrated on the edge of a drain and a gate, which results in poor device reliability. A current moving path is localized in the lower part of the field insulation layer so that concentration of impact ionization arises. Because breakdown happens on the surface of a semiconductor and concentration of electric field also exists on the surface of the semiconductor, the reliability of devices becomes degraded.

### BRIEF DESCRIPTION OF THE DRAWINGS

FIG. 1 is a cross-sectional view illustrating a known LDMOS device.

FIG. 2 is a cross-sectional view illustrating an example LDMOS device.

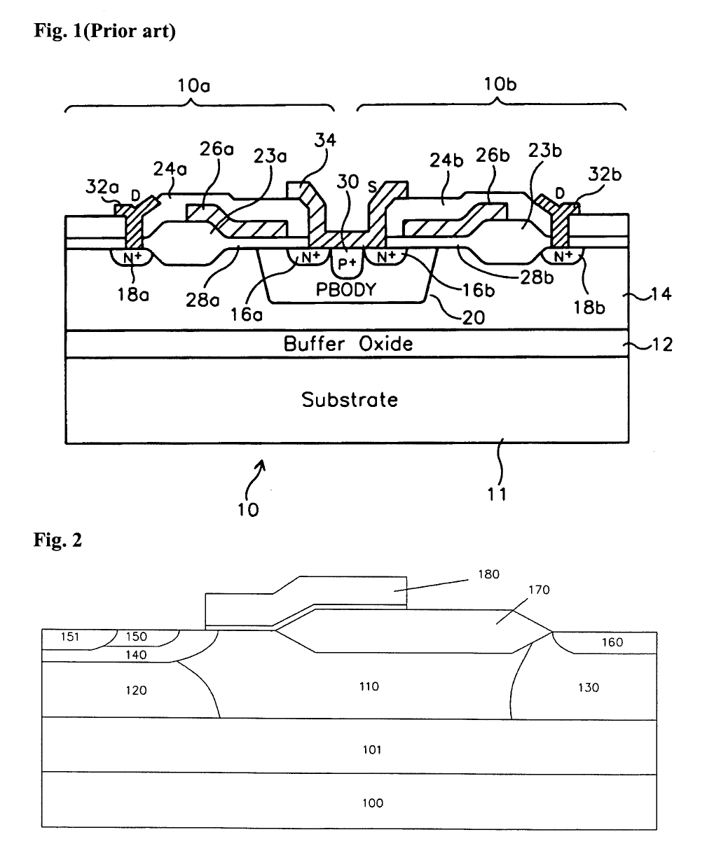

### DETAILED DESCRIPTION

An example LDMOS device having a P-type semiconductor substrate is described below. Although not described explicitly, the explanation is similarly applied to an example having an N-type semiconductor substrate.

Referring to FIG. 2, an N-type buried layer 101 doped at a high concentration is positioned on a P-type semiconductor substrate. The N-type buried layer 101 is preferably doped with a doping concentration between 1.0×10¹³/cm² and 1.0×10¹⁵/cm². The doping concentration of the N-type buried layer is determined by the desired breakdown voltage of an LDMOS transistor device. An N-type epitaxial layer 110 is positioned on the entire surface of the semiconductor substrate where the N-type buried layer 101 is positioned. Here, the epitaxial layer 110 preferably has lower doping concentration than that of the N-type buried layer 101.

Next, a P-type body region 140 is placed in the upper part of the epitaxial layer 110. Preferably, the P-type body region 140 is doped with a doping concentration of 1.0×10¹³/cm² and has a lower depth than the epitaxial layer 110. A P-type layer 120 with a high dopant concentration is buried between the P-type body region 140 and the N-type buried layer 101 to connect the P-type body region 140 and the N-type buried layer 101.

Next, a source region 150 is positioned in the upper part of the P-type body region 140. A P-type doping region 151 with high dopant concentration is positioned on the middle part of a source region 150 and a device isolation structure 170 is positioned on the upper part of a non-active region. A gate conductive layer 180 is positioned on some part of the P-type body region 140 and the device isolation structure 170, and a gate oxide layer is placed under the gate conductive layer 180.

Next, a drain region 160 is positioned above the N-type buried layer 101 and connected to the N-type buried layer 101 by an N-type doped region 130 having a high dopant concentration. The N-type doped region 130 is preferably doped through a POC13 process.

The operation of an LDMOS manufactured in accordance with the example method described above is now provided. First, if a voltage above a threshold voltage is applied to the gate conductive layer 180, an N-type channel is generated on the P-type body region 140, which is under the gate conductive layer 180. Carriers implanted into the source region 150 flow through the channel of the P-type body region 140 into the epitaxial layer 110 and, finally, go into the N-type doped region 130. However, in known devices, the carriers flow from a source region into a drain region through a well region having a low dopant concentration, which results in increased ON-resistance within the devices.

Accordingly, the disclosed method reduces the ON-resistance of the devices because the carriers flow through the N-type doped region with having a high dopant concentration instead of the epitaxial layer with low concentration. Furthermore, as this method induces a breakdown to occur between the P-type buried layer with ‘high’ concentration and the N-type buried layer with ‘high’ concentration, the ability of recovery and the reliability of the devices are improved.

This application claims the benefit of Korean Application No. 10-2003-0101105, filed on Dec. 31, 2003, which is hereby incorporated herein by reference in its entirety.

While the examples herein have been described in detail with reference to example embodiments, it is to be understood that the coverage of this patent is not limited to the disclosed embodiments, but, on the contrary, is intended to cover various modifications and equivalent arrangements included within the sprit and scope of the appended claims.

1. An LDMOS transistor comprising:
a semiconductor substrate of a first conductivity type;
a first buried layer of a second conductivity type on the semiconductor substrate;
an epitaxial layer of the second conductivity type on the first buried layer;
a body region of the first conductivity type in the upper part of the epitaxial layer;
a second buried layer of the first conductivity type between the body region and the first buried layer;
a source region of the second conductivity type in the upper part of the body region;
a drain region of the second conductivity type in the upper part of the epitaxial layer; and
a third buried layer of the second conductivity type between the drain region and the first buried layer.

2. An LDMOS transistor as defined by claim 1, wherein the first buried layer has a higher doping concentration than the semiconductor substrate.

3. An LDMOS transistor as defined by claim 1, wherein the first buried layer has a doping concentration determined by the desired breakdown voltage of the LDMOS transistor.

4. An LDMOS transistor as defined by claim 1, wherein a middle portion of the source region comprises a doping region of the first conductivity type.

5. An LDMOS transistor as defined by claim 1, wherein the second buried layer has a higher doping concentration than the body region.

6. An LDMOS transistor as defined by claim 1, wherein the third buried layer has a higher doping concentration than the drain region.
